(19) United States
(12) Patent Application Publication
(10) Pub. No.: US 2014/0125348 A1
(43) Pub. Date: May 8, 2014

(54) SYSTEM AND METHOD FOR ESTIMATING THE END-OF-CHARGE TIME OF A BATTERY

(71) Applicants: Fehd Ben-Aicha, Guyancourt (FR); Ana-Lucia Driemeyer-Franco, Montigny-Le-Bretonneux (FR); Claire Oberti, Paris (FR)

(72) Inventors: Fehd Ben-Aicha, Guyancourt (FR); Ana-Lucia Driemeyer-Franco, Montigny-Le-Bretonneux (FR); Claire Oberti, Paris (FR)

(73) Assignee: RENAULT S.A.S., Boulogne-Billancourt (FR)

(21) Appl. No.: 14/118,675

(22) PCT Filed: May 16, 2012
(86) PCT No.: PCT/FR12/51115

§ 371 Date: Jan. 16, 2014

(30) Foreign Application Priority Data
May 19, 2011 (FR) 1154383

(51) Int. Cl. G01R 31/36

(52) U.S. Cl. CPC G01R 31/3675
USPC 324/430; 324/426

(57) ABSTRACT

The invention relates to a system for estimating the end-of-charge time of a battery connected to a battery charger on board a motor vehicle. The system is characterised in that it comprises a means (1) for determining the charge status of a battery, a means (6) for determining the charge power of the battery charger and a means (11) for determining an end-of-charge time.

The technical field of the invention is that of systems for charging elements for storing electrical power.

The estimation of the charging end time of a battery represents an important piece of information for users of this type of power storage device. This information for example makes it easier for the user to make better use of the time spent waiting for the battery to charge. This information also allows on-board systems to better manage power use in an electric or hybrid vehicle in order to increase the range of the vehicle.

One aim of the invention is to allow the charging end time of a battery to be estimated with precision.

Another aim of the invention is to allow the charging end time of a battery subject to ageing to be estimated.

In one embodiment a system is provided for estimating the charging end time of a battery connected to a battery charger in an automotive vehicle. The system comprises a means for evaluating the charging state of a battery, a means for evaluating the charging power of the battery charger, and a means for evaluating a charging end time. The expression “charging state” is understood to mean the ratio of the current charge to the maximum charge.

This evaluating system has the advantage of taking into account the differences between the start and end of charging when evaluating the remaining charging time.

The means for evaluating a charging end time may comprise a means for evaluating a start-of-charging duration, and a means for evaluating an end-of-charging duration.

The system may comprise a means for correcting the charging end time depending on the ageing of the battery, which means is connected on the output side to the means for evaluating a charging end time, and able to modify the charging end time depending on the ageing state of the battery.

The means for evaluating a charging end time may comprise a means for modeling the battery, and a means for modeling the charging end time.

The means for modeling the battery allows the physical characteristics of the battery, which are non-linear, to be taken into account in order to improve the estimation of the charging end time.

The evaluating system thus has the advantage of returning an estimate more rapidly and of being more adaptable to different batteries.

The means for modeling the charging end time may be able to evaluate the charging end time as a function of a memorized model, of coefficients received from a means for modeling the battery, of a maximum charging value of the battery received from a memory, of a measurement of the charging state, of a measurement of the charging power, and of a measurement of the temperature of the battery received from a sensor of the temperature of the battery.

The system may comprise a means for evaluating the ageing of the battery, which means is connected between the memory and the means for evaluating the charging end time.

The system may comprise a filter downstream of the means for evaluating the charging state of a battery, and of the means for evaluating the charging power of the battery charger, allowing measurement noise to be attenuated.

Such a system for estimating the charging end time may be integrated into a device for controlling a battery, or into a device for controlling an automotive vehicle powertrain connected to a battery.

A method is also provided for evaluating the charging end time of a battery, in which the charging state of a battery is evaluated, the charging power of the battery charger is evaluated, and a charging end time is evaluated depending on the charging state and the charging power.

A correction to the charging end time may be evaluated depending on the ageing of the battery.

The charging end time may be evaluated as a function of a model, of a memorized maximum charging value, of a measurement of the charging state, of a measurement of the charging power, and of a measurement of the temperature of the battery.

Other aims, features and advantages will become apparent on reading the following description that is given merely by way of nonlimiting example and with reference to the appended drawings, in which:

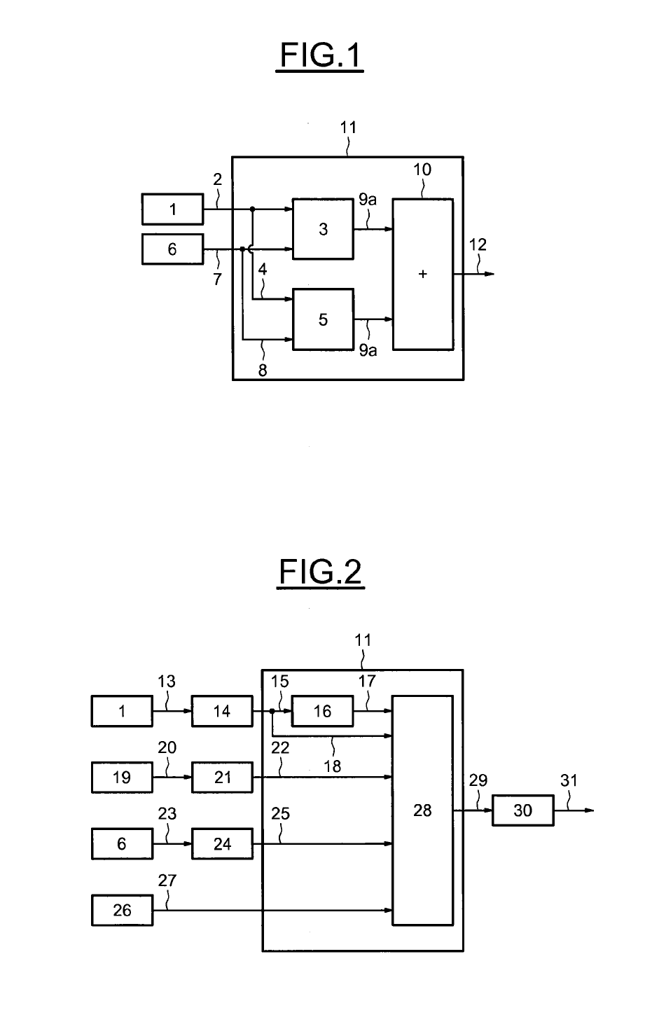

FIG. 1 illustrates a first embodiment of an evaluating system according to the invention; and

FIG. 2 illustrates a second embodiment of an evaluating system according to the invention.

FIG. 1 shows a means 1 for evaluating the charging state connected, by a connection 2, to a means for evaluating the start-of-charging duration, and, by a branch 4 from the connection 2, to a means 5 for evaluating the end-of-charging duration. A means 6 for evaluating the power of the battery charger is connected, by the connection 7, to the means 3 for evaluating the start-of-charging duration and, by a branch 8 from the connection 7, to the means 5 for evaluating the end-of-charging duration.

A summer 10 is connected, by a connection 9a, to the means 3 for evaluating the start-of-charging duration, and by a connection 9b to the means 5 for evaluating the end-of-charging duration.

A connection 12 is connected to an output of the summer 10.

The means 11 for evaluating the charging end time comprises the summer 10, the means 3 for evaluating the start-of-charging duration, and the means 5 for evaluating the end-of-charging duration.

In this first embodiment, the estimation of the charging end time relies on an empirical method using two maps. The estimation of the charging duration depends on the charging power and on the charging state of the battery. The maps used are therefore maps comprising two inputs and one output.

Two distinct phases are passed through to fully charge a battery. A full charge corresponds to charging a battery having a charging state equal to 0% of its full charge to a charging state equal to 100% of its full charge.

A first phase, called the “start-of-charging”, corresponds to a phase during which the charging power is constant.

A second phase, called the “end-of-charging”, corresponds to a phase during which the power is reduced in steps.

The map corresponding to the first phase is contained in the means 3 for evaluating the start-of-charging duration.

The map corresponding to the second phase is contained in the means 5 for evaluating the end-of-charging duration.

The summer 10 sums the durations obtained as output from the means 3 for evaluating the start-of-charging duration, and from the means 5 for evaluating the end-of-charging duration.

On ageing, batteries exhibit a decrease in their capacity, and therefore in the length of time taken to charge them.

However, the maps contained in the means 3 for evaluating the start-of-charging duration and in the means 5 for evaluating the end-of-charging duration are established for full charges corresponding to new batteries.

The charging state measured for an ageing battery therefore does not correspond to the charging state of a new battery. The evaluated charging duration will thus be erroneous unless corrected for ageing. It will be recalled that a charging state is expressed as a ratio of the current charge to the maximum charge of the battery.

In order to preserve a reliable estimation of the charging duration throughout the lifetime of a battery, it is necessary to correct the charging state values transmitted to the means 3 for evaluating the start-of-charging duration, and to the means 5 for evaluating the end-of-charging duration, in accordance with the second embodiment of the invention described with reference to FIG. 2.

To do this, a means for correcting the charging end time depending on the ageing of the battery may be inserted downstream of the means 1 for evaluating the charging state. Using a memorized value of the charge stored after a full charge, the means 1 for evaluating the charging state is able to evaluate the ageing state of the battery. It is also able to modify the value of the charging state determined by the means 1 for evaluating the charging state so that the value of the charging state transmitted as output, to the means 3 for evaluating the start-of-charging duration and to the means 5 for evaluating the end-of-charging duration, contains an ageing state correction.

The ageing state correction may for example be a multiplicative factor of the measured charging state. The multiplicative factor may be the ratio of the full charge of an ageing battery to the full charge of the same battery when new. This factor may also result from a law comparing the variation in the charging state of an ageing battery over time with that of a new battery. FIG. 2 shows a means 11 for evaluating the charging end time, comprising a means 16 for modeling the battery and a means 28 for estimating the charging end time.

A means 1 for evaluating the charging state is connected, by a connection 13, to a first filter 14. The filter 14 is connected, on the output side, to the means 16 for modeling the battery, which means is itself connected, on the output side, to a connection 17. A branch 18 is moreover connected to the connection 15.

A memory 19 is connected, by the connection 20, to a means 21 for evaluating the ageing of the battery, which means is itself connected, on the output side, to a connection 22.

A means 6 for evaluating the power of the battery charger is connected, by a connection 23, to a second filter 24, itself connected, on the output side, to a connection 25.

A means 26 for evaluating the temperature is connected, on the output side, to a connection 27.

The means 28 for estimating the charging end time is connected, on the input side, to the connections 17, 18, 22, 25 and 27. A third filter 30 is connected, on the input side, via the connection 29, to the means 28 for estimating the charging end time, and on the output side to a connection 31.

The means 28 for estimating the charging end time allows the physics of the charging of a battery to be modeled very precisely. It allows memory resources and time to be saved when obtaining an estimate from a system for estimating the charging end time of a battery, relative to a system using maps to characterize charging time for each possible operating point, i.e. for a series of preset temperatures, preset lifetimes, preset charging powers and preset charging states.

Alternatively, the means 21 for evaluating the ageing of the battery may be removed, in which case the means 28 for evaluating the charging end time employs directly the value memorized in the memory 19.

The second embodiment employs a physical model of the charging and discharging of the battery to evaluate the charging end time. The physical model characterizes the full charging duration as a function of the temperature of the battery, the charging power of the battery, the charging state, and the ageing of the battery.

In order to obtain this model, first the battery to be charged is modeled. To do this, the charging state SOC of the battery is expressed as a function of the battery current I^{bat}, of the temperature T of the battery, of the capacity of the new battery Q₀^{bat,max} and of the capacity of the battery at time t and temperature T, Q^{bat,max}(T, t).

$$\frac{d SOC}{d t} = \frac{{I}^{bat}}{{Q}^{bat , max} ( T , t )} \qquad ( Eq . 1 )$$

The capacity of the battery degrades depending on its temperature and its charging state. An expression relating voltage, current and resistance is deduced therefrom:

U^{bat}=U₀(T,SOC)+I^{bat}·R(T,SOC) (Eq. 2)

where U^{bat} is the voltage of the battery;
U₀(T,SOC) is the open-circuit voltage of the battery; and
R(T,SOC) is the resistance of the battery.

The open-circuit voltage and the internal resistance of the battery are either obtained from empirical maps, or from functions derived from the electrochemical theory of batteries, or from a combination of both.

Designing an estimating algorithm that specifically takes into account nonlinearities in the resistance and open-circuit voltage allows the precision of the estimation to be increased.

To do this, the capacity of the new battery Q₀^{bat′max} is considered to be a parameter of equation 1.

The charging power of the battery may be expressed in the following way:

P_{ch}=U^{bat}−I^{bat} (Eq. 3)

If, in equation 3, U^{bat} is substituted for its expression drawn from equation 2, the following expression is obtained:

P_{ch}=I^{bat}−[U₀(T,SOC)+I^{bat}·R(T,SOC)] (Eq. 4)

Equation 4 may be developed to obtain the following equation:

P_{ch}=I^{bat}−[U₀(T,SOC)+(I^{bat})·R(T,SOC) (Eq. 5)

Solving this equation allows the current I^{bat} to be determined:

$${I}^{bat} = \frac{- {U}_{0} ( T , SOC ) + \sqrt{{[ {U}_{0} ( T , SOC ) ]}^{2} + 4 \cdot {P}_{ch} \cdot R ( T , SOC )}}{2 \cdot R ( T , SOC )} \qquad ( Eq . 6 )$$

Replacing I^{bat} with its expression drawn from equation 6 in equation 1 gives:

$$\frac{d SOC}{d t} = \frac{- {U}_{0} ( T , SOC ) + \sqrt{{[ {U}_{0} ( T , SOC ) ]}^{2} + 4 \cdot {P}_{ch} \cdot R ( T , SOC )}}{2 \cdot R ( T , SOC ) \cdot {Q}^{bat , max} ( T , t )} \qquad ( Eq . 7 )$$

Equation 7 may be reformulated to express the time derivative dt:

$$d t = \frac{2 \cdot R ( T , SOC ) \cdot {Q}^{bat , max} ( T , t )}{- {U}_{0} ( T , SOC ) + \sqrt{{[ {U}_{0} ( T , SOC ) ]}^{2} + 4 \cdot {P}_{ch} \cdot R ( T , SOC )}} \cdot d SOC \qquad ( Eq . 8 )$$

Integration term by term of equation 8 allows the charging end time t^{f}_{ch} to be determined, the charging start time tⁱ_{ch} being given.

$${t}_{ch}^{f} = {t}_{ch}^{i} + {\int }_{{S}_{i}}^{{S}_{f}} \frac{2 \cdot R ( T , SOC ) \cdot {Q}^{bat , max} ( T , t )}{- {U}_{0} ( T , SOC ) + \sqrt{{[ {U}_{0} ( T , SOC ) ]}^{2} + 4 \cdot {P}_{ch} \cdot R ( T , SOC )}} \cdot d SOC \qquad ( Eq . 9 )$$

where:

Sᵢ is the value of the charging state SOC at the start of the charging; and

S_{f} is the value of the charging state SOC at the end of the charging, which value may be different from 100%.

Integration of equation 7 is difficult because of the complexity of the expressions of the open-circuit voltage U₀ and the resistance R.

In order to overcome this difficulty, a method for linearizing the open-circuit voltage U₀ and the resistance R is provided.

As described above, the curve of the open-circuit voltage as a function of charging state exhibits two inflection points bounding three separate zones. In each of these zones it is estimated that the open-circuit voltage varies linearly with charging state. It is thus possible to associate an index k with each of the three intervals.

For each of the zones, the open-circuit voltage may be expressed in the form of the following equation:

U₀=αₖ−SOC+βₖ (Eq. 10)

where:
k is an index varying between 0 and 2 and designating one of the three zones; of course it would be possible to split the open-circuit voltage curve into more than three zones; and
αₖ and βₖ are two coefficients.

The same reasoning may be applied to the variation in the internal resistance R as a function of the charging state of the battery. The variation in the internal resistance R is expressed as an inverse polynomial and comprises two zones in which the rate of variation is different. The abscissa of the boundary between the two zones is different from the abscissas of the boundaries separating the open-circuit voltage zones.

For each of the zones, the resistance may be expressed in the form of the following equation:

R=pₖ−SOC+τₖ (Eq. 11)

where:
k is an index equal to 0 or 1 and designating one of the two zones; of course it would be possible to split the internal resistance curve into more than two zones; and
pₖ and τₖ are two coefficients.

The coefficients αₖ, βₖ, pₖ and τₖ are set so that the relationships for the open-circuit voltage and the internal resistance approach linear functions. In addition, the coefficients may vary as a function of temperature and the type of battery.

If the index of the interval to which the initial value Sᵢ of the charging state SOC belongs is denoted kᵢ, and the index of the interval to which the final value S_{f} of the SOC belongs is denoted k_{f}, and equations 10 and 11 are considered, the expression (Eq. 9) defining the charging end time converts to the following expression:

$${t}_{ch}^{f} = {t}_{ch}^{i} + {\sum }_{ki < k < kf} {\int }_{Si}^{Sf} A ( T , SOC , {Q}^{bat , max} , {P}_{ch} ) \cdot d SOC \qquad ( Eq . 12 )$$

The final charging time is estimated in a succession of steps. First, the index kᵢ corresponding to the current charging state is determined. The index kᵢ is comprised between 0 and 3.

Next, equation 12 is applied, replacing the values of the resistance and open-circuit voltage in equation 9 with the linear expressions of equations 10 and 11, having taken care to choose the coefficients corresponding to the index kᵢ in question. The coefficients of these equations are set beforehand.

The evaluating system may be integrated into the main processor of the powertrain or into the processor of the battery.

One application of the second embodiment of the system for estimating the charging end time is the optimization of the charging strategy of the battery.

The length of time taken to charge the battery is decreased when the evaluating system is used. This is because the evaluating system allows the length of time taken to charge the battery to be minimized while minimizing dispersion in the charging of the battery. Minimization of the dispersion in the charging of the battery is obtained by maximizing the power accepted by the battery during charging. This is facilitated by analytical expression of the model of the evaluating system.

t_{ch}^{f}=f(I,SOC,T,P^{bat,max}) (Eq. 13)

where P^{bat,max} is the maximum power that the battery can accept without compromising its lifetime.

The dispersion in the value of the charging state SOC is denoted osoc. The dispersion in the value of the charging state of the battery is dependent on the dispersion σₗ in the current, itself dependent on the temperature T and the current I. The greater the current, the shorter the charging time. Similarly, the lower the current, the smaller the dispersion in the charging state, and the greater the respect of the constraint on the lifetime of the battery. Thus, there is a problem with optimization of the charging current. This problem may be solved by analytical or numerical methods.

Another application of the second embodiment of the system for estimating the charging end time is optimization of vehicle charging times interactively with the user in order to improve the durability, range and availability of the vehicle. The system allows the range of the vehicle and its availability to be improved. Via a human-machine interface, the user may be informed of the remaining charge, of the charging duration required for a full charge, and of a predicted recharging time. The user may also receive this information synthetically within a satellite-assisted navigation application (GPS for example) or any other route planning program.

1. A system for estimating a charging end time of a battery connected to a battery charger in an automotive vehicle, said system comprising a means for evaluating a charging state of a battery, a means for evaluating the charging power of the battery charger, and a means for evaluating the charging end time.

2. The system as claimed in claim 1, in which the means for evaluating the charging end time comprises a means for evaluating a start-of-charging duration, and a means for evaluating an end-of-charging duration.

3. The system as claimed in claim 2, comprising a means for correcting the charging end time depending on an ageing state of the battery, said means for correcting being connected on an output ride to the means for evaluating the charging end time, and configured to modify the charging end time depending on the ageing state of the battery.

4. The system as claimed in claim 1, wherein the means for evaluating the charging end time comprises a means for modeling the battery using a linearization of an open-circuit voltage and an internal resistance of the battery, and a means for estimating the charging end time.

5. The system as claimed in claim 4, wherein the means for estimating the charging end time is configured to evaluate the charging end time as a function of a memorized model, of coefficients received from a means for modeling the battery, of a maximum charging value of the battery received from a memory, of a measurement of the charging state, of a measurement of the charging power, and of a measurement of a temperature of the battery received from a sensor of the temperature of the battery.

6. The system as claimed in claim 5, comprising a means for evaluating an ageing of the battery, said means for evaluating the ageing is connected between a memory and to the means for evaluating the charging end time.

7. The system as claimed in claims 5, comprising a filter downstream of the means for evaluating the charging state of a battery, and of the means for evaluating the charging power of the battery charger, allowing measurement noise to be attenuated.

8. A method for evaluating a charging end time of a battery, said method comprising:
evaluating a charging state of a battery,
evaluating a charging power of a battery charger, and
evaluating a charging end time depending on the charging state and the charging power.

9. The method as claimed in claim 8, further comprising evaluating a correction to the charging end time depending on an ageing of the battery.

10. The method as claimed in claim 8, further comprising evaluating the charging end time as a function of a model, of a memorized maximum charging value, of a measurement of the charging state, of a measurement of the charging power, and of a measurement of the temperature of the battery.
